(19) United States
(12) Patent Application Publication
(10) Pub. No.: US 2011/0312117 A1
(43) Pub. Date: Dec. 22, 2011

(54) METHOD FOR MANUFACTURING SEMICONDUCTOR LIGHT EMITTING DEVICE

(75) Inventors: Aya SUZUKI, Kanagawa-ken (JP); Kazuhiro Akiyama, Fukuoka-ken (JP); Toshihide Izumiya, Tokyo (JP)

(73) Assignee: Kabushiki Kaisha Toshiba, Tokyo (JP)

(21) Appl. No.: 13/041,123

(22) Filed: Mar. 4, 2011

(30) Foreign Application Priority Data
Jun. 18, 2010 (JP) 2010-139854

(51) Int. Cl. H01L 33/32

(52) U.S. Cl. 438/47; 257/E33.025; 257/E33.027

(57) ABSTRACT

According to one embodiment, a method is disclosed for manufacturing a semiconductor light emitting device. The method can include forming an active layer including indium (In) on a heated substrate. The method can include forming a multiple-layer film made of a nitride semiconductor on the active layer in a state of the substrate being heated to substantially the same temperature as a temperature of the forming of the active layer. In addition, the method can include cooling the substrate to room temperature after the forming of the multiple-layer film.

### CROSS-REFERENCE TO RELATED APPLICATIONS

This application is based upon and claims the benefit of priority from Japanese Patent Application No. 2010-139854, filed on Jun. 18, 2010; the entire contents of which are incorporated herein by reference.

### FIELD

Embodiments described herein relate generally to a method for manufacturing a semiconductor light emitting device.

### BACKGROUND

A semiconductor light emitting device using nitride semiconductors generally has a structure in which an n-type layer, an active layer, and a p-type layer are provided with an interposed low-temperature buffer layer on a sapphire substrate. The crystallinity of each of the layers affects the luminous efficacy. The deposition temperature of each of the layers is one condition that influences the crystallinity.

### BRIEF DESCRIPTION OF THE DRAWINGS

FIG. 1A is a schematic cross-sectional view of semiconductor light emitting device of a first embodiment;

FIG. 1B is a schematic cross-sectional view illustrating a method for manufacturing the semiconductor light emitting device of the first embodiment;

FIG. 2A is a schematic cross-sectional view of a semiconductor light emitting device of a second embodiment;

FIG. 2B is a schematic cross-sectional view illustrating a method for manufacturing the semiconductor light emitting device of the second embodiment;

FIG. 3A are diagram illustrating the deposition sequence of the semiconductor light emitting device of the first embodiment, and FIG. 3B is a diagram illustrating the deposition sequence of the semiconductor light emitting device of the second embodiment; and

FIG. 4 is a graph illustrating the relation of the growth temperature difference between an active layer and layers thereon with the pit density and the light output.

### DETAILED DESCRIPTION

According to one embodiment, a method is disclosed for manufacturing a semiconductor light emitting device. The method can include forming an active layer including indium (In) on a heated substrate. The method can include forming a multiple-layer film made of a nitride semiconductor on the active layer in a state of the substrate being heated to substantially the same temperature as a temperature of the forming of the active layer. In addition, the method can include cooling the substrate to room temperature after the forming of the multiple-layer film.

Embodiments will now be described with reference to the drawings.

### First Embodiment

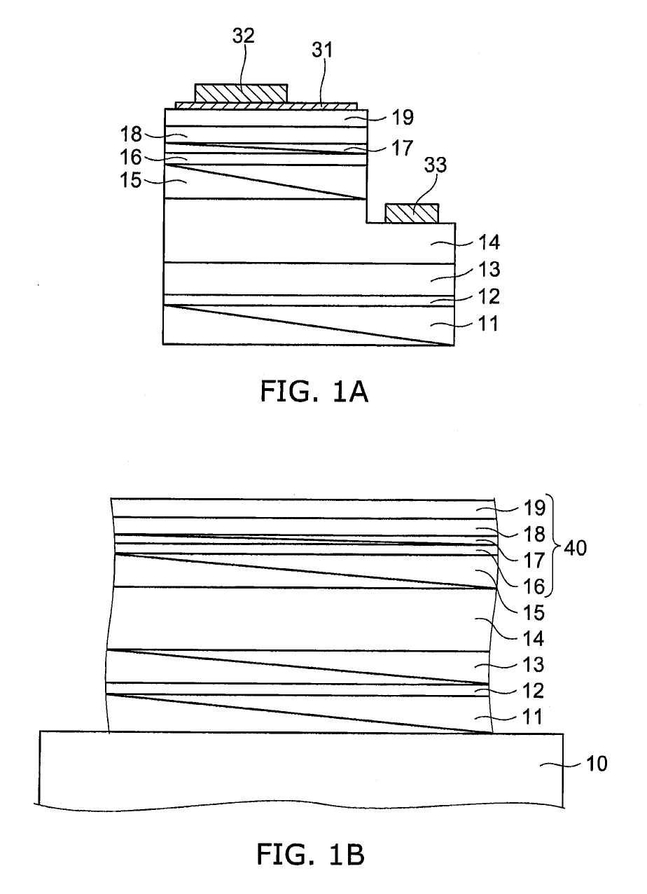

As shown in FIG. 1A, a stacked body of nitride semiconductor layers is provided on a substrate 11. The substrate 11 is, for example, a sapphire substrate including a (0001) surface. Each of the nitride semiconductor layers is epitaxially grown on the (0001) surface of the substrate 11, for example, using metal organic chemical vapor deposition (MOCVD).

The stacked body of nitride semiconductor layers includes a low-temperature buffer layer 12, a GaN layer 13, an n-type layer (or an n-type contact layer) 14, an active layer 15, cap layers 16 and 17, a p-type clad layer 18, and a p-type contact layer 19 formed in order from the substrate 11 side.

The low-temperature buffer layer 12 includes, for example, GaN. The GaN layer 13 is grown or deposited at a temperature higher than that of the low-temperature buffer layer 12. The low-temperature buffer layer 12 and the GaN layer 13 mitigate the lattice mismatch between the substrate 11 and the GaN-based semiconductors.

The n-type layer 14 is an n-type nitride semiconductor layer which includes, for example, GaN and to which, for example, silicon (Si) is doped as an n-type impurity.

The active layer 15 includes indium (In). The active layer 15 includes a multiple quantum well structure in which, for example, a well layer is repeatedly stacked alternately with a barrier layer having a bandgap larger than the bandgap of the well layer. The well layer includes, for example, In_{(X)}Ga_{(y)}Al_{(z)}N (0<X≦1, 0≦y, z≦1, x+y+z=1). The barrier layer includes, for example, In_{(X1)}Ga_{(y1)}Al_{(z1)}N (0≦X1≦1, 0≦y1, z1≦1, x1+y1+z1=1). x, y, z, x1, y1 and z1 are set to widen the bandgap of the barrier layer than the bandgap of the well layer. The well layer is undoped. The barrier layer is undoped or the n-type.

The cap layers 16 and 17 are nitride semiconductor layers which include, for example, an Al_{(X2)}Ga_{(1-X2)}N layer (0≦X2<1) and to which, for example, magnesium (Mg) is doped as a p-type impurity.

The p-type clad layer 18 and the p-type contact layer 19 are p-type nitride semiconductor layers which include, for example, an AlGaN layer and to which, for example, magnesium (Mg) is doped as a p-type impurity.

In the case where GaN layers are used as these AlGaN layers, the surface planarity is better than that of AlGaN layers; and the strain on the active layer 15 can be reduced.

The cap layers 16 and 17 have bandgaps larger than that of the active layer 15, form potential barriers for the active layer 15, suppress overflow of carriers, and trap carriers in the active layer 15. The p-type clad layer 18 supplies holes to the active layer 15. The p-type contact layer 19 ensures ohmic contact with the electrode.

A transparent electrode 31 is provided on the p-type contact layer 19. A p-side electrode 32 is provided on the transparent electrode 31. The transparent electrode 31 is transparent to the light emitted by the active layer 15 and is in ohmic contact with the p-type contact layer 19. A metal oxide such as, for example, indium tin oxide (ITO) may be used as the transparent electrode 31. The p-side electrode 32 is made of a metal material.

The n-type layer 14 includes a region where the active layer 15, the cap layers 16 and 17, the p-type clad layer 18, and the p-type contact layer 19 are not provided. An n-side electrode 33 is provided on the surface of the region. The n-side electrode 33 is made of a metal material and is in ohmic contact with the n-type layer 14.

A relatively low potential is applied to the n-side electrode 33, and a relatively high potential is applied to the p-side electrode 32. For example, a ground potential is applied to the n-side electrode 33, and a positive potential is applied to the p-side electrode 32. Thereby, electrons are injected into the active layer 15 from the n-type layer 14 side and holes are injected into the active layer 15 from the p-type layer side, and the electrons and the holes recombine in the active layer 15 to emit light.

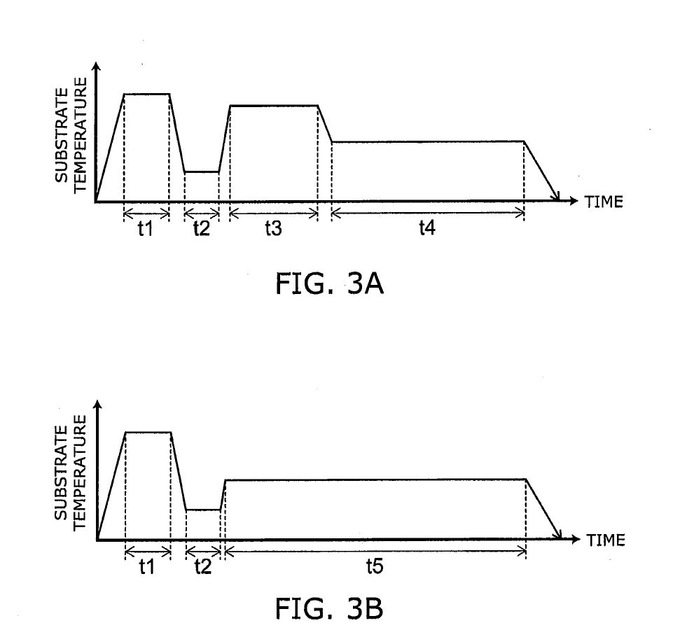

A method for manufacturing the semiconductor light emitting device of the first embodiment will now be described with reference to FIG. 1B and FIG. 3A.

FIG. 3A illustrates the growth sequence of each of the nitride semiconductor layers onto the substrate 11 of the semiconductor light emitting device of the first embodiment. The horizontal axis illustrates time and the vertical axis illustrates the heating temperature of the substrate 11.

The substrate 11 is supported on a susceptor 10 as illustrated in FIG. 1B inside a reaction container. The susceptor 10 includes a not-illustrated heating mechanism. Power is supplied to the heating mechanism of the susceptor 10 based on the control of a not-illustrated control apparatus to heat the susceptor 10. The substrate 11 supported on the susceptor 10 is heated by the heating of the susceptor 10. Accordingly, the substrate temperature corresponds to the set temperature (the control temperature) of the susceptor 10.

The source-material gases including the elements included In each of the nitride semiconductor layers are introduced into the reaction container. The source-material gases transported onto the heated substrate 11 react, and each of the nitride semiconductor layers is vapor-deposited. For example, ammonia may be used as one nitrogen source material.

Prior to the forming of the nitride semiconductor layers, heat treatment (thermal cleaning) is performed on the surface of the substrate 11 in, for example, a hydrogen atmosphere. The thermal cleaning is performed in the interval t1 of FIG. 3A. In the thermal cleaning, the substrate 11 is heated to, for example, about 1000° C., and the temperature is maintained at substantially a constant during the interval t1.

Then, the substrate temperature is reduced and the low-temperature buffer layer 12 is grown or deposited onto the (0001) surface of the substrate 11 made of, for example, sapphire. At this time, the substrate 11 is heated to, for example, 500 to 550° C. It is desirable for the film thickness of the low-temperature buffer layer 12 to be about 30 to 50 nm. It is desirable for the ammonia flow rate to be about 10 slm. It is desirable for the total flow rate of the source materials to be about 30 slm. It is desirable for the growth or deposition rate to be not more than 3 nm/minute. By the low-temperature buffer layer 12 being grown or deposited at not more than 3 nm/minute, the occurrence of pits in the GaN layer 13 of the upper layer can be suppressed, and the GaN layer 13 can be formed with good crystallinity. The low-temperature buffer layer 12 is grown or deposited in the interval t2 of FIG. 3A. The substrate temperature is maintained at substantially a constant during the interval t2.

Continuing, the substrate temperature is increased, and the GaN layer 13 is grown or deposited onto the low-temperature buffer layer 12. At this time, the substrate 11 is heated to, for example, 1000 to 1200° C. Then, the n-type layer 14 is grown or deposited onto the GaN layer 13 at the same substrate temperature. It is desirable for the film thickness of the n-type layer 14 to be about 5 to 6 μm. It is desirable for the ammonia flow rate to be about 10 slm. It is desirable for the total flow rate of the source materials to be about 30 slm. It is desirable for the growth or deposition rate to be not less than 2 μm/hour.

The GaN layer 13 and the n-type layer 14 are grown or deposited in the interval t3 of FIG. 3A. The substrate temperature is maintained at substantially a constant during the interval t3.

Then, the substrate temperature is reduced, and the active layer 15 is grown or deposited onto the n-type layer 14. At this time, the substrate 11 is heated to, for example, 750 to 850° C.

Continuing, the cap layer 16 is grown or deposited onto the active layer 15 at the same substrate temperature. It is desirable for the film thickness of the cap layer 16 to be about 5 nm. It is desirable for the ammonia flow rate to be about 30 slm. It is desirable for the growth or deposition rate to be about 2 nm/minute.

Then, the cap layer 17 is grown or deposited onto the cap layer 16 at the same substrate temperature. It is desirable for the film thickness of the cap layer 17 to be about 5 nm. It is desirable for the ammonia flow rate to be about 4 slm. It is desirable for the growth or deposition rate to be about 4 nm/minute.

Continuing, the p-type clad layer 18 is grown or deposited onto the cap layer 17 at the same substrate temperature. It is desirable for the film thickness of the p-type clad layer 18 to be about 80 nm. It is desirable for the ammonia flow rate to be about 4 slm. It is desirable for the growth or deposition rate to be about 40 nm/minute.

Then, the p-type contact layer 19 is grown or deposited onto the p-type clad layer 18 at the same substrate temperature. It is desirable for the film thickness of the p-type contact layer 19 to be about 5 nm. It is desirable for the ammonia flow rate to be about 4 slm. It is desirable for the growth or deposition rate to be about 2 nm/minute.

The active layer 15, the cap layers 16 and 17, the p-type clad layer 18, and the p-type contact layer 19 are grown or deposited in the interval t4 of FIG. 3A. The substrate temperature is maintained at substantially a constant during the interval t4.

In other words, the active layer 15, the cap layers 16 and 17, the p-type clad layer 18, and the p-type contact layer 19 are grown or deposited in a state in which the set temperature of the susceptor 10 is controlled at a constant and the heating temperature of the substrate 11 is maintained at substantially the same temperature. Herein, being at substantially the same temperature is not limited to temperatures having the exact same value and includes fluctuation of about 10° C. which is in a range that does not affect the crystallinity of each of the layers.

In this embodiment, a multiple-layer film 40 including the cap layers 16 and 17, the p-type clad layer 18, and the p-type contact layer 19 is grown or deposited on the active layer 15 at the same temperature as the temperature of the growth or deposition of the active layer 15 after forming the active layer 15. Accordingly, after forming the active layer 15, the active layer 15 is not reheated to a temperature higher than the temperature of the growth or deposition of the active layer 15. Thereby, crystal degradations, in which pits and the like undesirably occur in particularly the In_{(X)}Ga_{(y)}Al_{(z)}N (0<X≦1, 0≦y, z≦1, x+y+z=1) used in the active layer 15, can be suppressed. As a result, a highly efficient semiconductor light emitting device having few crystal defects can be provided.

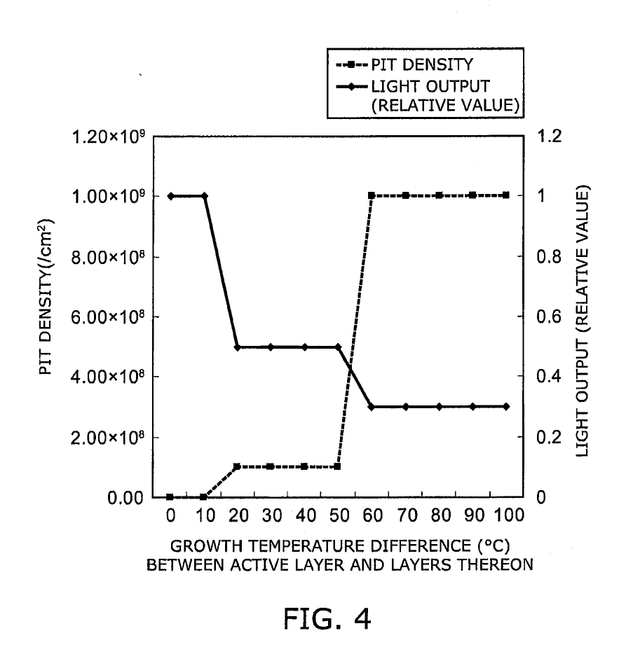

In FIG. 4, the horizontal axis illustrates the growth or deposition temperature difference (° C.) between the active layer 15 and the layers thereon (the multiple-layer film 40). The growth or deposition temperature difference corresponds to the heating temperature difference of the substrate 11. The vertical axis of the left side illustrates the pit density (the defect density) (/cm²), and the vertical axis of the right side illustrates the light output (a relative value). The solid line illustrates the change of the light output, and the broken line illustrates the change of the pit density.

In the graph of FIG. 4, the pit density decreases and the light output increases as the growth or deposition temperature difference between the active layer 15 and the layers thereon decreases. The pit density and the light output when the growth or deposition temperature difference between the active layer 15 and the layers thereon is not more than 10° C. have the same values as when the growth or deposition temperatures of the active layer 15 and the layers thereon are the same (when the growth or deposition temperature difference is 0). Accordingly, as described above, it can be said that being at substantially the same temperature corresponds to a growth or deposition temperature difference between the active layer 15 and the layers thereon of 0 to 10° C.

The PL intensity also has a characteristic similar to that of the light output and exhibits the highest value when the growth or deposition temperature difference is not more than 10° C. The PL intensity also has the same value when the growth or deposition temperature difference is not more than 10° C. as when the growth or deposition temperature difference is 0° C.

As described above, the pit density can be reduced and the light output and the PL intensity can be increased by using substantially the same growth or deposition temperature for the active layer 15 and the layers thereon such that the growth or deposition temperature difference between the active layer 15 and the layers thereon is within 10° C.

In the case where the active layer 15 has a structure including a barrier layer and a well layer, there are cases where the growth or deposition temperatures (the heating temperature of the substrate 11 or the set temperature of the susceptor 10) of the barrier layer and the well layer are different. For example, although there is a tendency for the growth or deposition temperature of the barrier layer to be higher than that of the well layer, the growth or deposition temperature of the barrier layer does not degrade the crystallinity of the well layer in such a case. Accordingly, the crystallinity of the well layer and the barrier layer is not degraded by growing or depositing the cap layers 16 and 17, the p-type clad layer 18, and the p-type contact layer 19 at substantially the same temperature as the growth or deposition temperature of the barrier layer.

Even in the case where the growth or deposition temperature of the well layer is higher than that of the barrier layer, the crystallinity of the well layer and the barrier layer is not degraded by growing or depositing the cap layers 16 and 17, the p-type clad layer 18, and the p-type contact layer 19 at substantially the same temperature as the growth or deposition temperature of the well layer.

Further, in the case where a GaN layer not including In is used as the n-type layer 14, the number of the crystal defects of the n-type layer (the GaN layer) 14 can be reduced by increasing the growth or deposition temperature of the n-type layer (GaN layer) 14 to exceed the growth or deposition temperature of the active layer 15 including In.

After forming the multiple-layer film 40, that is, after the interval t4 of FIG. 3A has elapsed, the substrate temperature is reduced to room temperature. Subsequently, annealing is performed in, for example, a nitrogen atmosphere inside a reaction container to reduce the resistance of the multiple-layer film 40. The annealing temperature at this time is lower than the temperature of the growth or deposition of the active layer 15. Accordingly, degradation of the crystallinity due to reheating the active layer 15 does not occur.

After the annealing, the wafer, in which the nitride semiconductor layers described above are formed on the substrate 11, is removed from the reaction container. A protective film is formed on the surface of the p-type contact layer 19, and a portion of the p-type contact layer 19, the p-type clad layer 18, the cap layers 17 and 16, and the active layer 15 is removed using, for example, reactive ion etching (RIE). Thereby, the surface of a portion of the n-type layer 14 is exposed.

Then, the transparent electrode 31 is formed on the p-type contact layer 19, and the p-side electrode 32 is formed thereon. The n-side electrode 33 is formed on the exposed n-type layer 14 surface.

### Second Embodiment

Components similar to those of the first embodiment are marked with like reference numerals, and a detailed description thereof may be omitted.

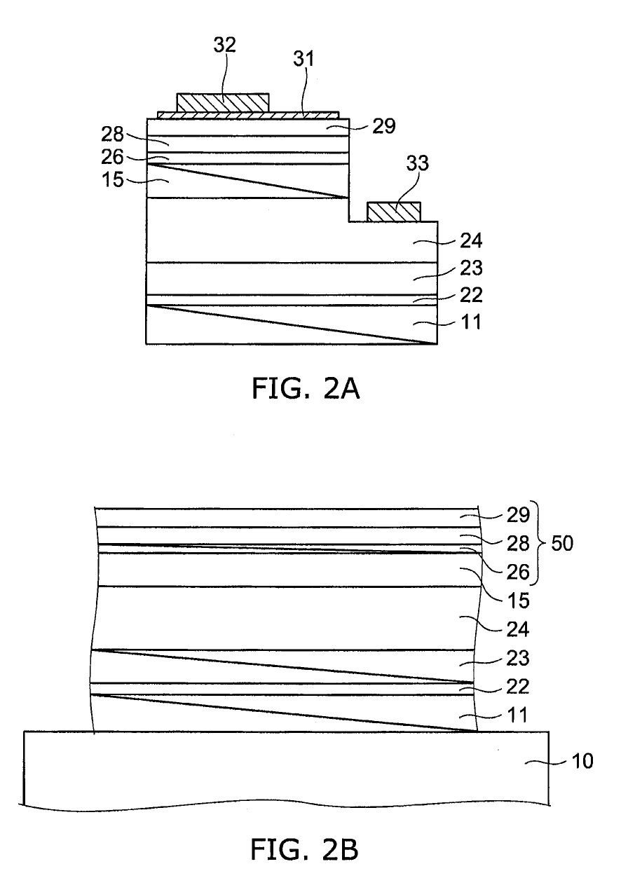

As shown in FIG. 2A, a stacked body of nitride semiconductor layers is provided on the substrate 11. The substrate 11 is, for example, a sapphire substrate including a (0001) surface. Each of the nitride semiconductor layers is epitaxially grown on the (0001) surface of the substrate 11 using, for example, MOCVD.

The stacked body of nitride semiconductor layers includes a low-temperature buffer layer 22, an InGaN layer 23, an n-type layer (or an n-type contact layer) 24, the active layer 15, a cap layer 26, a p-type clad layer 28, and a p-type contact layer 29 formed in order from the substrate 11 side.

The low-temperature buffer layer 22 includes, for example, In_{X}Ga_{1-X}N (0<X<0.1). The InGaN layer 23 is grown or deposited at a temperature higher than that of the low-temperature buffer layer 22. The low-temperature buffer layer 22 and the InGaN layer 23 mitigate the lattice mismatch between the substrate 11 and the GaN-based semiconductors.

The n-type layer 24 is an n-type nitride semiconductor layer which includes, for example, In_{X}Ga_{1-X}N (0<x<0.06) and to which, for example, silicon (Si) is doped as an n-type impurity.

The active layer 15 includes indium (In) similarly to the first embodiment.

The cap layer 26 is a nitride semiconductor layer which includes, for example, In_{X}Ga_{1-X}N (0<X<0.06) and to which, for example, magnesium (Mg) is doped as a p-type impurity.

The p-type clad layer 28 and the p-type contact layer 29 are p-type nitride semiconductor layers which include, for example, In_{X}Ga_{1-X}N (0<X<0.06) and to which, for example, magnesium (Mg) is doped as a p-type impurity.

The cap layer 26 has a bandgap larger than that of the active layer 15, forms a potential barrier for the active layer 15, suppresses overflow of carriers, and traps carriers in the active layer 15. The p-type clad layer 28 supplies electron holes to the active layer 15. The p-type contact layer 29 ensures ohmic contact with the electrode.

The transparent electrode 31 is provided on the p-type contact layer 29. The p-side electrode 32 is provided on the transparent electrode 31. The transparent electrode 31 is transparent to the light emitted by the active layer 15 and is in ohmic contact with the p-type contact layer 29.

The n-type layer 24 includes a region where the active layer 15, the cap layer 26, the p-type clad layer 28, and the p-type contact layer 29 are not provided. The n-side electrode 33 is provided on the surface of the region. The n-side electrode 33 is in ohmic contact with the n-type layer 24.

The ground potential is applied to the n-side electrode 33, and a positive potential is applied to the p-side electrode 32. Thereby, electrons are injected from the n-type layer 24 side into the active layer 15, holes are injected from the p-type layer side into the active layer 15, and the electrons and the holes recombine in the active layer 15 to emit light.

A method for manufacturing the semiconductor light emitting device of the second embodiment will now be described with reference to FIG. 2B and FIG. 3B.

FIG. 3B illustrates the growth sequence of each of the nitride semiconductor layers onto the substrate 11 of the semiconductor light emitting device of the second embodiment. The horizontal axis illustrates time and the vertical axis illustrates the heating temperature of the substrate 11.

In this embodiment as well, the substrate 11 is supported on the susceptor 10 as illustrated in FIG. 2B inside a reaction container. The substrate 11 supported on the susceptor 10 is heated by the heating of the susceptor 10.

The source-material gases including the elements included in each of the nitride semiconductor layers are introduced into the reaction container. The source-material gases transported onto the heated substrate 11 react, and each of the nitride semiconductor layers is vapor-deposited.

Prior to forming the nitride semiconductor layers, heat treatment (thermal cleaning) is performed on the surface of the substrate 11 in, for example, a hydrogen atmosphere. The thermal cleaning is performed in the interval t1 of FIG. 3B. In the thermal cleaning, the substrate 11 is heated to, for example, about 1000° C., and the temperature is maintained at substantially a constant during the interval t1.

Then, the substrate temperature is reduced, and the low-temperature buffer layer 22 is grown or deposited on the (0001) surface of the substrate 11 made of, for example, sapphire. At this time, the substrate 11 is heated to, for example, 500 to 550° C. It is desirable for the film thickness of the low-temperature buffer layer 22 to be about 30 to 50 nm. It is desirable for the growth or deposition rate to be not more than 3 nm/minute. By the low-temperature buffer layer 22 being grown or deposited at not more than 3 nm/minute, the occurrence of pits in the InGaN layer 23 of the upper layer can be suppressed, and the InGaN layer 23 can be formed with good crystallinity. The low-temperature buffer layer 22 is grown or deposited in the interval t2 of FIG. 3B. The substrate temperature is maintained at substantially a constant during the interval t2.

Continuing, the substrate temperature is increased, and the InGaN layer 23 is grown or deposited on the low-temperature buffer layer 22. At this time, the substrate 11 is heated to, for example, 750 to 850° C. It is desirable for the film thickness of the InGaN layer 23 to be not more than 6 μm.

Then, the n-type layer 24 is grown or deposited on the InGaN layer 23 at the same substrate temperature. It is desirable for the film thickness of the n-type layer 24 to be not more than 6 μm.

Continuing, the active layer 15 is grown or deposited on the n-type layer 24 at the same substrate temperature.

Then, the cap layer 26 is grown or deposited on the active layer 15 at the same substrate temperature.

Continuing, the p-type clad layer 28 is grown or deposited on the cap layer 26 at the same substrate temperature. It is desirable for the film thickness of the p-type clad layer 28 to be not more than 100 nm.

Then, the p-type contact layer 29 is grown or deposited on the p-type clad layer 28 at the same substrate temperature.

The InGaN layer 23, the n-type layer 24, the active layer 15, the cap layer 26, the p-type clad layer 28, and the p-type contact layer 29 are grown or deposited in the interval t5 of FIG. 3B. The substrate temperature is maintained at substantially a constant during the interval t5.

In other words, the InGaN layer 23, the n-type layer 24, the active layer 15, the cap layer 26, the p-type clad layer 28, and the p-type contact layer 29 above the low-temperature buffer layer 22 are grown or deposited in a state in which the set temperature of the susceptor 10 is controlled at a constant and the heating temperature of the substrate 11 is maintained at substantially the same temperature. Herein, being at substantially the same temperature is not limited to temperatures having the exact same value and includes fluctuation of about 10° C. which is in a range that does not affect the crystallinity of each of the layers.

In this embodiment as well, a multiple-layer film 50 including the cap layer 26, the p-type clad layer 28, and the p-type contact layer 29 formed on the active layer 15 is grown or deposited at the same temperature as the temperature of the growth or deposition of the active layer 15 after forming the active layer 15. Accordingly, after forming the active layer 15, the active layer 15 is not reheated to a temperature higher than the temperature of the growth or deposition of the active layer 15. Thereby, crystal degradations, in which pits and the like undesirably occur in particularly the InGaN used in the active layer 15, can be suppressed. As a result, a highly efficient semiconductor light emitting device having few crystal defects can be provided.

In this embodiment as well, similarly to the embodiment described above, the pit density can be reduced and the light output and the PL emission intensity can be increased by using substantially the same temperature for the growth or deposition temperature of the active layer 15 and the layers thereon such that the growth or deposition temperature difference between the active layer 15 and the layers thereon (the multiple-layer film 50) is within 10° C. as in the graph of FIG. 4.

Lattice mismatch can be reduced, the decrease of the recombination probability due to piezoelectric fields can be suppressed, and crystal defects can be suppressed by using InGaN layers by adding In to all of the nitride semiconductor layers (the low-temperature buffer layer 22, the InGaN layer 23, the n-type layer 24, the active layer 15, the cap layer 26, the p-type clad layer 28, and the p-type contact layer 29) epitaxially grown on the substrate 11. As a result, a more highly efficient semiconductor light emitting device can be provided.

Further, the refractive index between the active layer 15 and the layers thereon and thereunder approach each other. The total internal reflection angles increase, and the light extraction efficiency increases.

Moreover, because the InGaN layer 23, the n-type layer 24, the cap layer 26, the p-type clad layer 28, and the p-type contact layer 29 are InGaN layers similar to the active layer 15, the temperature suited to the growth or deposition of these layers is the same as the temperature suited to the growth or deposition of the active layer 15. Accordingly, all of the nitride semiconductor layers above the low-temperature buffer layer 22 can be grown or deposited at the same temperature as illustrated by the interval t5 in FIG. 3B. As a result, it is unnecessary to increase and reduce the substrate temperature for each of the layers. Accordingly, the wait time to increase or reduce to the prescribed temperature is unnecessary, and the processing efficiency can be increased.

The average In composition of the n-type layer 24 is lower than the average In composition of the active layer 15. Also, the average In composition of each of the p-type layers is lower than the average In composition of the active layer 15. Thereby, it is easy to grow or deposit the n-type layer 24 and each of the p-type layers with few defects.

After forming the multiple-layer film 50, that is, after the interval t5 of FIG. 3B has elapsed, the substrate temperature is reduced to room temperature. Subsequently, annealing is performed, for example, in a nitrogen atmosphere inside a reaction container to reduce the resistance of the multiple-layer film 50. The annealing temperature at this time is lower than the temperature of the growth or deposition of the active layer 15. Accordingly, degradation of the crystallinity due to reheating the active layer 15 does not occur.

After the annealing, the wafer, in which the nitride semiconductor layers described above are formed on the substrate 11, is removed from the reaction container. A protective film is formed on the surface of the p-type contact layer 29, and a portion of the p-type contact layer 29, the p-type clad layer 28, the cap layer 26, and the active layer 15 is removed using, for example, RIE. Thereby, the surface of a portion of the n-type layer 24 is exposed.

Then, the transparent electrode 31 is formed on the p-type contact layer 29, and the p-side electrode 32 is formed thereon. The n-side electrode 33 is formed on the exposed n-type layer 24 surface.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor light emitting device, comprising:
forming an active layer including indium (In) on a heated substrate;
forming a multiple-layer film made of a nitride semiconductor on the active layer in a state of the substrate being heated to substantially the same temperature as a temperature of the forming of the active layer; and
cooling the substrate to room temperature after the forming of the multiple-layer film.

2. The method of claim 1, wherein
the substrate is supported by a susceptor including a heating mechanism and the substrate is heated via the susceptor, and
a set temperature of the susceptor is constant in the forming of the active layer and the forming of the multiple-layer film.

3. The method of claim 2, wherein
the substrate is supported by the susceptor inside a reaction container, and
the active layer and the multiple-layer film are vapor-deposited on the heated substrate by introducing a source-material gas into the reaction container.

4. The method of claim 1, further comprising forming an n-type layer on the substrate by increasing the temperature of the substrate to a temperature higher than the temperature of the forming of the active layer prior to the forming of the active layer.

5. The method of claim 1, further comprising forming a low-temperature buffer layer including GaN on the substrate by reducing the temperature of the substrate to a temperature lower than the temperature of the forming of the active layer prior to the forming of the active layer.

6. The method of claim 5, further comprising forming a GaN layer on the low-temperature buffer layer by increasing the temperature of the substrate to a temperature higher than the temperature of the forming of the active layer prior to the forming of the active layer.

7. The method of claim 6, further comprising forming an n-type layer including GaN and not including In on the GaN layer by increasing the temperature of the substrate to a temperature higher than the temperature of the forming of the active layer prior to the forming of the active layer.

8. The method of claim 5, further comprising performing thermal cleaning of a surface of the substrate by increasing the temperature of the substrate to a temperature higher than the temperature of the forming of the active layer prior to the forming of the low-temperature buffer layer.

9. The method of claim 1, wherein indium is added to the multiple-layer film in the forming of the multiple-layer film.

10. The method of claim 9, further comprising forming an n-type layer including indium (In) on the substrate by heating the substrate to substantially the same temperature as the temperature of the forming of the active layer prior to the forming of the active layer.

11. The method of claim 10, wherein an average composition of In in the n-type layer is lower than an average composition of In in the active layer.

12. The method of claim 10, further comprising forming an InGaN layer on the substrate by heating the substrate to substantially the same temperature as the temperature of the forming of the active layer prior to the forming of the n-type layer.

13. The method of claim 12, further comprising forming a low-temperature buffer layer including InGaN on the substrate by reducing the temperature of the substrate to a temperature lower than the temperature of the forming of the active layer prior to the forming of the InGaN layer.

14. The method of claim 13, further comprising performing thermal cleaning of a surface of the substrate by increasing the temperature of the substrate to a temperature higher than the temperature of the forming of the active layer prior to the forming of the low-temperature buffer layer.

15. The method of claim 1, wherein the forming of the active layer includes repeatedly stacking a well layer alternately with a barrier layer having a bandgap larger than a bandgap of the well layer.

16. The method of claim 15, wherein
the barrier layer is formed by increasing the temperature of the substrate to a temperature higher than a temperature of the forming of the well layer, and
the multiple-layer film is formed in a state of the substrate being heated to substantially the same temperature as the temperature of the forming of the barrier layer.

17. The method of claim 1, wherein the forming of the multiple-layer film includes forming a p-type cap layer having a bandgap larger than a bandgap of the active layer on the active layer.

18. The method of claim 17, wherein the forming of the multiple-layer film further includes forming a p-type clad layer and a p-type contact layer on the p-type cap layer.

19. The method of claim 1, wherein the forming of the multiple-layer film includes forming a p-type GaN layer on the active layer.

20. The method of claim 1, further comprising annealing the multiple-layer film by reducing the temperature of the substrate to a temperature lower than the temperature of the forming of the active layer after the forming of the multiple-layer film.
